(19) United States
(12) Patent Application Publication
(10) Pub. No.: US 2026/0357930 A1
(43) Pub. Date: Nov. 12, 2026

(54) INTERFACE PIECE FOR FLUIDIC CONNECTION

(71) Applicant: ASM IP Holding B.V., Almere (NL)

(72) Inventors: Marco Dirkmaat, Woudenberg (NL); Klaas Boonstra, Hilversum (NL); Frans Wiegers, Vleuten (NL)

(21) Appl. No.: 19/666,472

(22) Filed: May 4, 2026

Related U.S. Application Data
(60) Provisional application No. 63/801,246, filed on May 7, 2025.

(51) Int. Cl. F16L 23/02; F16L 25/00; H10P 72/00

(52) U.S. Cl. CPC F16L 23/02; F16L 25/0018; H10P 72/0402

(57) ABSTRACT

The disclosure relates to an interface piece for connecting two gas pipes, in particular in a semiconductor manufacturing tool. Each gas pipe has a convex end that can be received in a concave cavity of the interface piece. One of the gas pipes is in a material with a higher thermal expansion than the interface piece. To accommodate the difference in thermal expansion, the radius of curvature of the cavity for this gas pipe is higher than the radius of curvature of the cavity for the other gas pipe.

### CROSS-REFERENCE TO RELATED APPLICATIONS

This application claims priority to U.S. Provisional Patent Application Ser. No. 63/801,246 filed May 7, 2025 titled INTERFACE PIECE FOR FLUIDIC CONNECTION, the disclosure of which is hereby incorporated by reference in its entirety.

### FIELD OF THE DISCLOSURE

The present disclosure relates to an interface piece for fluidically connecting a first gas channel ending at an end of a first pipe and a second gas channel ending at an end of a second pipe in a semiconductor manufacturing tool.

### BACKGROUND OF THE DISCLOSURE

In a semiconductor manufacturing tool, such as an oxidation tool, an anneal tool, or a vapor deposition tool, some gases or liquids must be conducted along a hermetic pathway between their delivery vessel and a reaction chamber to react with a substrate. The pathway typically includes several components that must be hermetically connected in high temperature environment, for example above 500 °C. A problem may occur when several components of the pathway are in different materials because a fluidic connection that is hermetic at room temperature may become leaky as temperature rises because of a difference in the thermal expansion of its components. There is therefore a need for a connection between components of a fluidic pathway that remains hermetic at high temperatures, typically at temperatures higher than 500 °C.

### SUMMARY OF THE DISCLOSURE

It is an object of the present disclosure to provide a fluidic connection for a semiconductor manufacturing tool to connect components of different materials.

According to a first aspect, the disclosure provides for an interface piece for fluidically connecting a first gas channel ending at an end of a first pipe and a second gas channel ending at an end of a second pipe in a semiconductor manufacturing tool, and comprising: a first cavity for receiving the end of the first pipe, and having a curved surface portion having an axial symmetry about a symmetry axis and being of a first radius of curvature in any plane including the symmetry axis; a second cavity for receiving the end of the second pipe, diametrically opposed to the first cavity, and having a curved surface portion having an axial symmetry about the symmetry axis and being of a second radius of curvature in any plane including the symmetry axis, the second radius of curvature being higher than the first radius of curvature; and a through-hole fluidically connecting the first cavity and the second cavity to fluidically connect the first gas channel and the second gas channel.

The second cavity having a curved surface with a higher radius of curvature provides more space to the end of the second pipe to expand with temperature. Both cavities have a curved surface portion of axial symmetry to accommodate for misalignment and thermal expansion of the pipes.

In embodiments, the interface piece comprises a shoulder suitable to apply a pressure pushing the interface piece against the second pipe.

In embodiments, the interface piece is in a first material, the first material being a ceramic material.

In embodiments, the interface piece is in a first material, the first material being selected from the group consisting of silicon carbide, gallium nitride, cubic boron arsenide, graphene, diamond, aluminum nitride, boron nitride, titanium carbide, zirconium carbide, tungsten carbide, molybdenum disilicide, hafnium carbide, niobium carbide, tantalum carbide, vanadium carbide, chromium carbide, silicon nitride, boron carbide, titanium diboride, zirconium diboride, aluminum oxide, or a mixture thereof.

In embodiments, the curved surface portion of the first cavity is a spherical segment.

In embodiments, the curved surface portion of the second cavity is a spherical segment.

In embodiments, the first radius of curvature is between 5 mm and 50 mm.

In embodiments, the second radius of curvature is between 5 mm and 100 mm.

In embodiments, the curved surface portion of the second cavity at a junction between the second cavity and the through-hole makes an angle φ with a direction parallel to the symmetry axis that is higher than 45°.

According to a second aspect, the disclosure provides for a connection arrangement for a semiconductor manufacturing tool comprising: a first pipe having a first gas channel and a curved end with an external surface which has an axial symmetry about a symmetry axis and is of a first radius of curvature in any plane including the symmetry axis, the first gas channel ending at said external surface of the curved end of the first pipe; a second pipe having a second gas channel and a curved end with an external surface which has an axial symmetry about the symmetry axis and is of a second radius of curvature in any plane including the symmetry axis, the second gas channel ending at said external surface of the curved end of second pipe, the second radius of curvature being higher than the first radius of curvature; and an interface piece fluidically connecting the first gas channel and the second gas channel, and comprising: a first cavity receiving the curved end of the first pipe, and having a curved surface portion which has an axial symmetry about the symmetry axis and is of the first radius of curvature in any plane including the symmetry axis to correspond to the external surface of the curved end of the first pipe; a second cavity receiving the curved end of the second pipe, diametrically opposed to the first cavity, and having a curved surface portion which has an axial symmetry about the symmetry axis and is of the second radius of curvature in any plane including the symmetry axis to correspond to the external surface of the curved end of the second pipe; and a through-hole fluidically connecting the first cavity and the second cavity to fluidically connect the first gas channel and the second gas channel; wherein the interface piece and the second pipe are in different materials.

In embodiments, the interface piece and the second pipe are such that the thermal expansion coefficient of the material of the second pipe is higher than the thermal expansion coefficient of the material of the interface piece.

In embodiments, the second pipe is in a second material, the second material being a ceramic material.

In embodiments, the second pipe is in a second material, the second material being selected from the group consisting of silicon oxide, graphite, alumina, zirconia, silicon carbide, silicon nitride, boron nitride, magnesia, tungsten carbide, mullite, yttria, hafnia, titania, beryllia, lanthanum hexaboride, tantalum carbide, niobium carbide, chromium oxide, thorium oxide, uranium oxide, calcium aluminate, zirconium silicate or a mixture thereof.

In embodiments, the second pipe comprises a shoulder around the second gas channel, the shoulder being suitable to apply a pressure pushing the second pipe against the interface piece.

In embodiments, the connection arrangement comprises a retainer maintaining the external surface of the curved end of the second pipe against the curved surface portion of the second cavity.

In embodiments, the external surface of the curved end of the second pipe at an extremity of the second pipe makes an angle α2 with a direction parallel to the symmetry axis that is higher than 45°.

In embodiments, the end of the second pipe forms a ball joint.

According to a third aspect, the disclosure provides for a semiconductor manufacturing tool comprising: a delivery vessel comprising a gas; a reaction chamber suitable to receive a substrate; a first pipe having a first gas channel and a curved end with an external surface which has an axial symmetry about a symmetry axis and is of a first radius of curvature in any plane including the symmetry axis, the first gas channel ending at said external surface of the curved end of the first pipe; a second pipe having a second gas channel and a curved end with an external surface which has an axial symmetry about the symmetry axis and is of a second radius of curvature in any plane including the symmetry axis, the second gas channel ending at said external surface of the curved end of second pipe, the second radius of curvature being higher than the first radius of curvature; and an interface piece fluidically connecting the first gas channel and the second gas channel, and comprising:
a first cavity receiving the curved end of the first pipe, and having a curved surface portion which has an axial symmetry about the symmetry axis and is of the first radius of curvature in any plane including the symmetry axis to correspond to the external surface of the curved end of the first pipe;
a second cavity receiving the curved end of the second pipe, diametrically opposed to the first cavity, and having a curved surface portion which has an axial symmetry about the symmetry axis and is of the second radius of curvature in any plane including the symmetry axis to correspond to the external surface of the curved end of the second pipe; and
a through-hole fluidically connecting the first cavity and the second cavity to fluidically connect the first gas channel and the second gas channel;
   wherein the interface piece and the second pipe are in different materials; and
   wherein the first pipe connects the interface piece and the reaction chamber and the second pipe connects the delivery vessel and the interface piece.

In embodiments, the semiconductor manufacturing tool is an oxidation tool, an anneal tool, or a vapor deposition tool.

In embodiments, the semiconductor manufacturing tool is configured to heat the interface piece to a temperature of at least 500 °C.

### BRIEF DESCRIPTION OF THE DRAWING FIGURES

These and further aspects of the disclosure will be explained in greater detail by way of examples and with reference to the accompanying drawings in which:

FIG. 1 illustrates a cross-section of a connection arrangement according to the present disclosure;

FIG. 2 illustrates a cross-section of a connection arrangement according to the present disclosure;

FIG. 3 illustrates a 3D view of a connection arrangement according to the present disclosure;

FIG. 4 illustrates a 3D view of a part of a connection arrangement according to the present disclosure;

FIG. 5 illustrates a cross-section of a connection arrangement according to the present disclosure;

FIG. 6 illustrates a 3D view of a connection arrangement according to the present disclosure; and

FIG. 7 is a schematic illustration of a semiconductor manufacturing tool according to the present disclosure.

### DETAILED DESCRIPTION

The present disclosure will be described with respect to particular embodiments and with reference to certain drawings but the disclosure is not limited thereto. The drawings described are only schematic and are non limiting. In the drawings, the size of some of the elements may be exaggerated and not drawn on scale for illustrative purposes.

Furthermore, the terms first, second, third and the like in the description and in the claims, are used for distinguishing between similar elements and not necessarily for describing a sequential or chronological order. The terms are interchangeable under appropriate circumstances and the embodiments of the disclosure can operate in other sequences than described or illustrated herein.

Furthermore, the various embodiments, although referred to as “preferred” are to be construed as exemplary manners in which the disclosure may be implemented rather than as limiting the scope of the disclosure.

The term “comprising”, used in the claims, should not be interpreted as being restricted to the elements or steps listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising A and B” should not be limited to devices consisting only of components A and B, rather with respect to the present disclosure, the only enumerated components of the device are A and B, and further the claim should be interpreted as including equivalents of those components.

In the frame of the present document a semiconductor manufacturing tool may be a tool, machine, or equipment in which a gas is delivered to a reaction chamber for processing a substrate. It may be, for example, an oxidation apparatus, an anneal apparatus, a chemical vapor deposition tool, an atomic layer deposition tool, an epitaxy tool, a molecular deposition tool, or another gas-delivery semiconductor processing apparatus.

In the frame of the present document, a delivery vessel refers to a vessel that is suitable for or configured for delivery of a substance that is contained within the vessel, preferably a gas or a liquid. The delivery vessel comprises an outer wall that encloses a cavity for storing and/or holding the substance and a fluid outlet for allowing a part of the substance to exit the cavity. The substance contained within the cavity may be a composition that is suitable for semiconductor processing methods, including oxidation, annealing, vapor deposition, etch, cleaning, or surface treatment methods. For example, the substance contained within the cavity may comprise one or more oxidizing gases, one or more inert gases, one or more reducing gases one or more precursors, one or more reactants, one or more etchants, or one or more surface treatment agents, as applicable. The substance contained within the cavity may be a homogeneous or heterogenous mixture. The substance contained within the cavity may be in a solid form, a liquid form, a gaseous form, or a combination thereof. The delivery vessel may be a draw vessel, a carrier vessel, a double walled vessel, a sublimation vessel, and/or other configuration.

In the frame of the present document, a reaction chamber is a space where a process involving a substrate, preferably a wafer, may be controlled. For example, it may be a chamber wherein oxidation, annealing, vapor deposition, etching, or another semiconductor process may be carried out. The reaction chamber may be a single wafer reactor. Alternatively, the reaction chamber may be a batch reactor. The reaction chamber can form part of a semiconductor processing assembly for manufacturing semiconductor devices. The processing assembly may comprise one or more multi-station processing chambers. In some embodiments, the substrate is moved between processing stations of a multi-station processing chamber. The reaction chamber may be part of a cluster tool in which different processes are performed to form an integrated circuit. In some embodiments, the semiconductor manufacturing tool is a thermal processing apparatus in which the fluidic connection is exposed to elevated temperature during operation. The disclosed interface piece may be particularly advantageous in oxidation tools and anneal tools because such tools can involve sustained high-temperature operation while maintaining a hermetic gas pathway between components made of different materials. However, the disclosed interface piece is not limited to such tools and may also be used in vapor deposition tools and other semiconductor manufacturing tools.

In the frame of the present document, an axial symmetry describes the property of an object that looks the same after being rotated by any angle around the symmetry axis.

In the frame of the present document, a spherical segment is a portion of a sphere included between two parallel planes.

In the frame of the present document, a surface of an element may mean the full surface of the element or part of the full surface of the element.

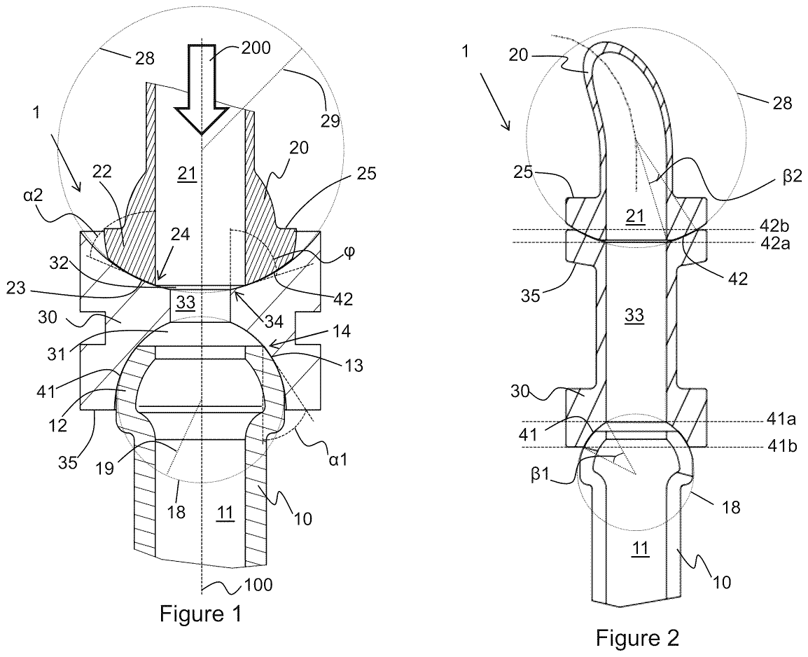

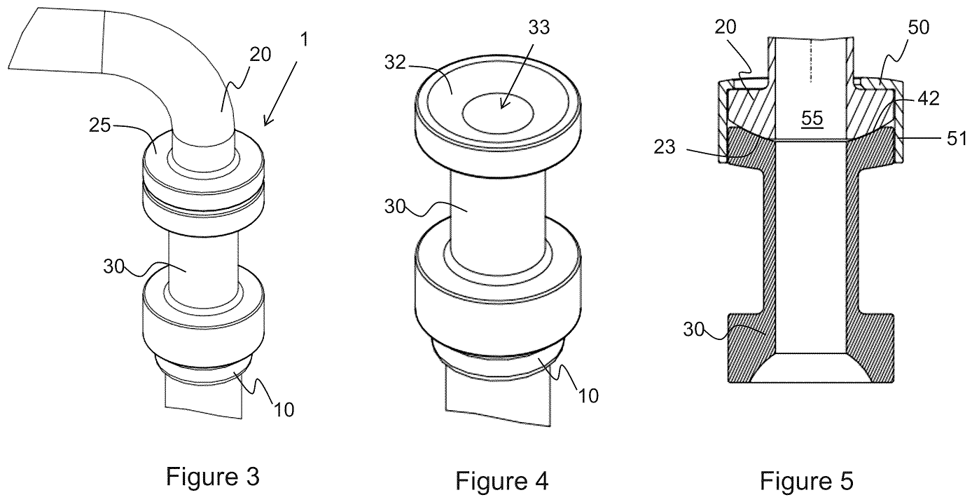

FIGS. 1, 2, and 3 represent a connection arrangement 1 according to the present disclosure. FIG. 4 represents a part of connection arrangement according to the present disclosure. A connection arrangement 1 according to the present disclosure comprises a first pipe 10, a second pipe 20 and an interface piece 30. The first pipe 10 has a first gas channel 11 and a curved end 12 with an external surface 13 that has an axial symmetry about a symmetry axis 100. The first gas channel 11 is opened at the external surface 13 of the curved end 12 of the first pipe 10. The second pipe 20 has a second gas channel 21 and a curved end 22 with an external surface 23 that has an axial symmetry about the symmetry axis 100. The second pipe 20 may be curved, as visible in particular at FIG. 3. The second gas channel 21 is opened at the external surface 23 of the curved end 22 of the second pipe 20.

The interface piece 30 mechanically connects the first pipe 10 and the second pipe 20. The interface piece 30 is preferably monolithic. The interface piece 30 fluidically connects the first gas channel 11 and the second gas channel 21. It comprises a first cavity 31 receiving the curved end 12 of the first pipe 10. The first cavity 31 has a curved surface portion 41 which has an axial symmetry about the symmetry axis 100 and matches the external surface 13 of the curved end 12 of the first pipe 10. The interface piece 30 also comprises a second cavity 32 receiving the curved end 22 of the second pipe 20. The second cavity 32 has a curved surface portion 42 which has an axial symmetry about the symmetry axis 100 and matches the external surface 23 of the curved end 22 of the second pipe 20. The second cavity 32 is diametrically opposed to the first cavity 31. The interface piece 30 also comprises a through-hole 33 fluidically connecting the first cavity 31 and the second cavity 32 and thus the first gas channel 11 and the second gas channel 21.

The external surface 13 of the curved end 12 of the first pipe 10 and the curved surface portion 41 of the first cavity 31 are of a first radius of curvature 19 in any plane including the symmetry axis 100. A first circle 18 in FIG. 1 has such first radius of curvature 19. The external surface 23 of the curved end 22 of the second pipe 20 and the curved surface portion 42 of the second cavity 32 are of a second radius of curvature 29 in any plane including the symmetry axis 100. A second circle 28 in FIG. 1 has such second radius of curvature 29. In the present disclosure the second radius of curvature 29 is higher than the first radius of curvature 19 in order to accommodate a higher thermal expansion for the second pipe 20 than for the first pipe 10.

In embodiments, the first radius of curvature 19 is between 5 mm and 50 mm, preferably between 10 mm and 20 mm, more preferably between 14 mm and 15 mm.

In embodiments, the second radius of curvature 29 is between 5 mm and 100 mm, preferably between 10 mm and 40 mm, more preferably between 20 mm and 30 mm.

Any of the external surface 13 of the curved end 12 of the first pipe 10, the external surface 23 of the curved end 22 of the second pipe 20, the curved surface portion 41 of the first cavity 31, and the curved surface portion 42 of the second cavity 32 may have the shape of a spherical segment. The curved surface portion 41 of the first cavity 31 may be a spherical segment between a proximal plane 41a and a distal plane 41b, both planes 41a, 41b being perpendicular to the symmetry axis 100. A first central angle β1 delimiting the spherical segment forming the curved surface portion 41 is preferably at least 5°, more preferably at least 10°, even more preferably 20°. The curved surface portion 42 of the second cavity 42 may be a spherical segment between a proximal plane 42a and a distal plane 42b, both planes 42a, 42b being perpendicular to the symmetry axis 100. A second central angle β2 delimiting the spherical segment forming the curved surface portion 42 is preferably at least 5°, more preferably at least 10°, even more preferably 15°. In some embodiments, the first central angle β1 is higher than the second central angle β2.

In some embodiments, the external surface 13 of the curved end 12 of the first pipe 10 and the curved surface portion 41 of the first cavity 31 are spherical segments of a sphere having a radius of curvature equal to the first radius of curvature 19. In some embodiments, the external surface 23 of the curved end 22 of the second pipe 22 and the curved surface portion 42 of the second cavity 32 are spherical segments of a sphere having a radius of curvature equal to the second radius of curvature 29.

In embodiments, the curved end 12 of the first pipe 10 forms a ball joint and/or the curved end 22 of the second pipe 20 forms a ball joint.

At a junction 34 between the second cavity 32 and the through-hole 33, the curved surface portion 42 of the second cavity 32 makes an angle φ with a direction parallel to the symmetry axis 100. φ is preferably higher than 45°, more preferably higher than 60°.

At an extremity 14 of the first pipe 10, in other words at the position of the external surface 13 that is the closest to the through-hole 33, the external surface 13 of the curved end 12 of the first pipe 10 makes an angle α1 with a direction parallel to the symmetry axis 100. α1 is preferably lower than 60°, more preferably lower than 45°.

At an extremity 24 of the second pipe 20, in other words at the position of the external surface 23 that is the closest to the through-hole 33, the external surface 23 of the curved end 22 of the second pipe 20 makes an angle α2 with a direction parallel to the symmetry axis 100. α2 is preferably higher than 45°, more preferably higher than 60°.

The second pipe 20 may comprise a shoulder 25 around the second gas channel 21. The shoulder 25 is suitable to apply a pressure pushing the second pipe 25 against the interface piece 30. The shoulder 25 preferably comprises a surface essentially perpendicular to the symmetry axis 100.

The interface piece 30 may comprise a shoulder 35 suitable to apply a pressure pushing the interface piece 30 against the second pipe 20. The shoulder 35 may be for example around the first cavity 31 or around the through-hole 33. The shoulder 35 preferably comprises a surface essentially perpendicular to the symmetry axis 100.

The interface piece 30 may be in a first material that is a ceramic material, for example any of or a mixture of silicon carbide, gallium nitride, cubic boron arsenide, graphene, diamond, aluminum nitride, boron nitride, titanium carbide, zirconium carbide, tungsten carbide, molybdenum disilicide, hafnium carbide, niobium carbide, tantalum carbide, vanadium carbide, chromium carbide, silicon nitride, boron carbide, titanium diboride, zirconium diboride, aluminum oxide.

The first pipe 10 may be in a material that is a ceramic material, for example any of or a mixture of silicon carbide, gallium nitride, cubic boron arsenide, graphene, diamond, aluminum nitride, boron nitride, titanium carbide, zirconium carbide, tungsten carbide, molybdenum disilicide, hafnium carbide, niobium carbide, tantalum carbide, vanadium carbide, chromium carbide, silicon nitride, boron carbide, titanium diboride, zirconium diboride, aluminum oxide.

The interface piece 30 and the first pipe 10 are preferably such that a ratio between the thermal expansion coefficient of the material of the interface piece 30 and the thermal expansion coefficient of the material of the first pipe 10 is between 0.5 and 2.0, or, more preferably, between 0.9 and 1.1. The first pipe 10 is preferably in the same material or a material chemically close to the first material.

The second pipe 20 is in a second material different than the first material. The second material is preferably a ceramic material, for example any of or a mixture of silicon oxide, graphite, alumina, zirconia, silicon carbide, silicon nitride, boron nitride, magnesia, tungsten carbide, mullite, yttria, hafnia, titania, beryllia, lanthanum hexaboride, tantalum carbide, niobium carbide, chromium oxide, thorium oxide, uranium oxide, calcium aluminate, zirconium silicate. The second material may be a crystalline or an amorphous form of any of these materials.

The thermal expansion coefficient of the second material is preferably higher than the thermal expansion coefficient of the first material. For example, the first material may be quartz with a coefficient of thermal expansion between 0.5×10⁻⁶/°C and 0.6×10⁻⁶/°C and the second material may be silicon carbide with a coefficient of thermal expansion between 3.0×10⁻⁶/°C and 4.0×10⁻⁶/°C.

The interface piece 30 and the second pipe 20 are such that a ratio α₃₀/α₂₀ between the thermal expansion coefficient of the material of the interface piece 30, α₃₀, and the thermal expansion coefficient of the material of the second pipe 20, α₂₀, is preferably lower than 0.5, more preferably lower than 0.2, even more preferably lower than 0.1.

The connection created by the connection arrangement 1 according to the present disclosure is especially hermetic. For example, a flow of gas 200, for example a flow of vapor, may flow, successively, in the second gas channel 21, the through-hole 33 and the first gas channel 11 without or with very little leak. In some embodiments, the gas 200 may be an oxidizing gas, an annealing gas, a precursor gas, a carrier gas, or a vapor.

FIG. 4 illustrates the first pipe 10 together with the interface piece 30. The second cavity 32 is especially visible on this figure.

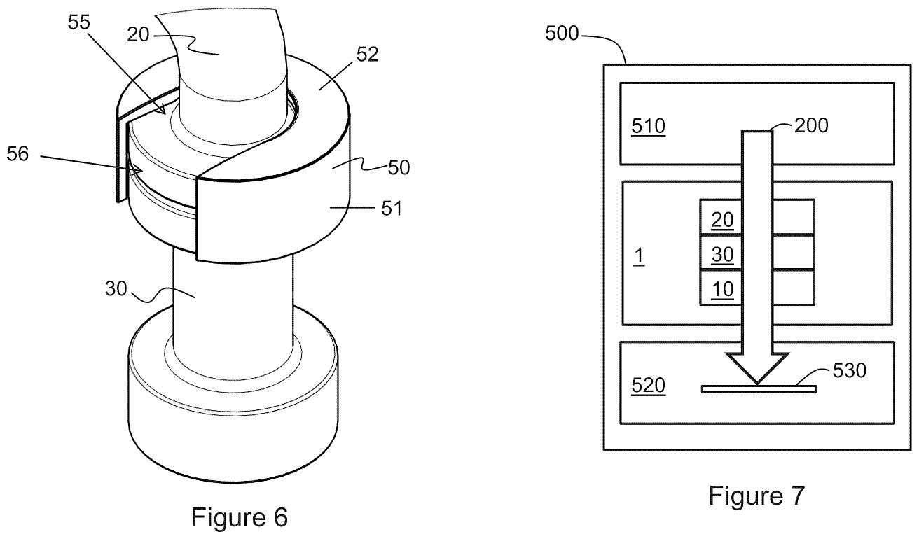

FIGS. 5 and 6 illustrates a retainer 50 maintaining the external surface 23 of the curved end 22 of the second pipe 20 against the curved surface portion 42 of the second cavity 32. In embodiments, the retainer 50 comprises a circumferential wall 51 around the curved surface portion 42 and the curved end 22, and/or a pushing surface 52 pushing the shoulder 25 of the second pipe 20. The circumferential wall 51 and the pushing surface 52 delimit a space 55 receiving the curved end 22 of the second pipe 20 and the curved surface portion 42 of the second cavity 32. The space 55 may be open opposite to the pushing surface 52, as illustrated at FIG. 5, or may be closed opposite to the pushing surface 52 by another surface pushing the shoulder 35 of the interface piece 30 against the second pipe 20. The space 55 has preferably an opening 56 suitable to insert the second pipe 20 in the space 55. The opening 56 preferably extends in a direction parallel to the symmetry axis 100 and circumferentially. Other embodiments of the retainer 50 are possible within the scope of the present disclosure.

As illustrated at FIG. 7, the connection arrangement 1 described in the present disclosure may, in particular, be used in a semiconductor manufacturing tool 500, for example an oxidation tool, an anneal tool, or a vapor deposition tool. In some embodiments, the semiconductor manufacturing tool 500 comprises a delivery vessel 510, the connection arrangement 1, and a reaction chamber 520. The first pipe 10 fluidically connects, directly or indirectly, the interface piece 30 and the reaction chamber 520 and the second pipe 20 fluidically connects, directly or indirectly, the delivery vessel 510 and the interface piece 30. The gas 200 delivered by the delivery vessel 510 moves successively within the second pipe 20, the interface piece 30, the first pipe 10 and the reaction chamber 520 where it contacts a substrate 530. In other words, in the pathway followed by the gas between the delivery vessel 510 and the reaction chamber 520, the first pipe 10 is downstream the interface piece 30 and the second pipe 20 is upstream the interface piece 30. Within the semiconductor manufacturing tool 500, the connection arrangement 1 is preferably at a temperature above 500 °C.

The connection arrangement 1 according to the disclosure may be arranged vertically as shown on the figures, or horizontally, or in any direction.

In other words, the disclosure relates to an interface piece 30 for connecting two gas pipes 10, 20, in particular in a semiconductor manufacturing tool 500. Each gas pipe 10, 20 has a convex end 12, 22 that can be received in a concave cavity 31, 32 of the interface piece 30. One 20 of the gas pipes is in a material with a higher thermal expansion than the interface piece 30. To accommodate the difference in thermal expansion, the radius of curvature 29 of the cavity 32 for this gas pipe 20 is higher than the radius of curvature 19 of the cavity 31 for the other gas pipe 10.

Although the present disclosure has been described above with respect to particular embodiments, it will readily be appreciated that other embodiments are also possible.

Various features and characteristics are described in this specification and illustrated in the drawings to provide an overall understanding of the disclosure. It is understood that the various features and characteristics described in this specification and illustrated in the drawings can be combined, within the scope of the claims, in any operable manner regardless of whether such features and characteristics are expressly described or illustrated in combination in this specification.

What is claimed is:

1. An interface piece for fluidically connecting a first gas channel ending at an end of a first pipe and a second gas channel ending at an end of a second pipe in a semiconductor manufacturing tool, and comprising:
a first cavity
for receiving the end of the first pipe, and
having a curved surface portion having an axial symmetry about a symmetry axis and being of a first radius of curvature in any plane including the symmetry axis;
a second cavity
for receiving the end of the second pipe,
diametrically opposed to the first cavity, and
having a curved surface portion having an axial symmetry about the symmetry axis and being of a second radius of curvature in any plane including the symmetry axis, the second radius of curvature being higher than the first radius of curvature; and
a through-hole fluidically connecting the first cavity and the second cavity to fluidically connect the first gas channel and the second gas channel.

2. The interface piece of claim 1, comprising a shoulder suitable to apply a pressure pushing the interface piece against the second pipe.

3. The interface piece of claim 1, being in a first material, the first material being a ceramic material.

4. The interface piece of claim 1, being in a first material, the first material being selected from the group consisting of silicon carbide, gallium nitride, cubic boron arsenide, graphene, diamond, aluminum nitride, boron nitride, titanium carbide, zirconium carbide, tungsten carbide, molybdenum disilicide, hafnium carbide, niobium carbide, tantalum carbide, vanadium carbide, chromium carbide, silicon nitride, boron carbide, titanium diboride, zirconium diboride, aluminum oxide, or a mixture thereof.

5. The interface piece of claim 1, wherein the curved surface portion of the first cavity is a spherical segment.

6. The interface piece of claim 1, wherein the curved surface portion of the second cavity is a spherical segment.

7. The interface piece of claim 1, wherein the first radius of curvature is between 5 mm and 50 mm.

8. The interface piece of claim 1, wherein the second radius of curvature is between 5 mm and 100 mm.

9. The interface piece of claim 1, wherein the curved surface portion of the second cavity at a junction between the second cavity and the through-hole makes an angle φ with a direction parallel to the symmetry axis that is higher than 45°.

10. A connection arrangement for a semiconductor manufacturing tool comprising:
a first pipe having a first gas channel and a curved end with an external surface which has an axial symmetry about a symmetry axis and is of a first radius of curvature in any plane including the symmetry axis, the first gas channel ending at said external surface of the curved end of the first pipe;
a second pipe having a second gas channel and a curved end with an external surface which has an axial symmetry about the symmetry axis and is of a second radius of curvature in any plane including the symmetry axis, the second gas channel ending at said external surface of the curved end of second pipe, the second radius of curvature being higher than the first radius of curvature; and
an interface piece fluidically connecting the first gas channel and the second gas channel, and comprising:
a first cavity receiving the curved end of the first pipe, and having a curved surface portion which has an axial symmetry about the symmetry axis and is of the first radius of curvature in any plane including the symmetry axis to correspond to the external surface of the curved end of the first pipe;
a second cavity receiving the curved end of the second pipe, diametrically opposed to the first cavity, and having a curved surface portion which has an axial symmetry about the symmetry axis and is of the second radius of curvature in any plane including the symmetry axis to correspond to the external surface of the curved end of the second pipe; and
a through-hole fluidically connecting the first cavity and the second cavity to fluidically connect the first gas channel and the second gas channel;
wherein the interface piece and the second pipe are in different materials.

11. The connection arrangement of claim 10, wherein the interface piece and the second pipe are such that the thermal expansion coefficient of the material of the second pipe is higher than the thermal expansion coefficient of the material of the interface piece.

12. The connection arrangement of claim 11, wherein the interface piece and the second pipe are such that a ratio α₃₀/α₂₀ between the thermal expansion coefficient of the material of the interface piece 30, α₃₀, and the thermal expansion coefficient of the material of the second pipe 20, α₂₀, is lower than 0.5.

13. The connection arrangement of claim 10, wherein the second pipe is in a second material, the second material being a ceramic material.

14. The connection arrangement of claim 10, wherein the second pipe is in a second material, the second material being selected from the group consisting of silicon oxide, graphite, alumina, zirconia, silicon carbide, silicon nitride, boron nitride, magnesia, tungsten carbide, mullite, yttria, hafnia, titania, beryllia, lanthanum hexaboride, tantalum carbide, niobium carbide, chromium oxide, thorium oxide, uranium oxide, calcium aluminate, zirconium silicate or a mixture thereof.

15. The connection arrangement of claim 10, wherein the second pipe comprises a shoulder around the second gas channel, the shoulder being suitable to apply a pressure pushing the second pipe against the interface piece.

16. The connection arrangement of claim 10, further comprising a retainer maintaining the external surface of the curved end of the second pipe against the curved surface portion of the second cavity.

17. The connection arrangement of claim 10, wherein the external surface of the curved end of the second pipe at an extremity of the second pipe makes an angle α2 with a direction parallel to the symmetry axis that is higher than 45°.

18. A semiconductor manufacturing tool comprising:
a delivery vessel comprising a gas;
a reaction chamber suitable to receive a substrate;
a first pipe having a first gas channel and a curved end with an external surface which has an axial symmetry about a symmetry axis and is of a first radius of curvature in any plane including the symmetry axis, the first gas channel ending at said external surface of the curved end of the first pipe;
a second pipe having a second gas channel and a curved end with an external surface which has an axial symmetry about the symmetry axis and is of a second radius of curvature in any plane including the symmetry axis, the second gas channel ending at said external surface of the curved end of second pipe, the second radius of curvature being higher than the first radius of curvature; and
an interface piece fluidically connecting the first gas channel and the second gas channel, and comprising:
a first cavity receiving the curved end of the first pipe, and having a curved surface portion which has an axial symmetry about the symmetry axis and is of the first radius of curvature in any plane including the symmetry axis to correspond to the external surface of the curved end of the first pipe;
a second cavity receiving the curved end of the second pipe, diametrically opposed to the first cavity, and having a curved surface portion which has an axial symmetry about the symmetry axis and is of the second radius of curvature in any plane including the symmetry axis to correspond to the external surface of the curved end of the second pipe; and
a through-hole fluidically connecting the first cavity and the second cavity to fluidically connect the first gas channel and the second gas channel;
wherein the interface piece and the second pipe are in different materials; and
wherein the first pipe connects the interface piece and the reaction chamber and the second pipe connects the delivery vessel and the interface piece.

19. The semiconductor manufacturing tool of claim 18, wherein the semiconductor manufacturing tool is an oxidation tool, an anneal tool, or a vapor deposition tool.

20. The semiconductor manufacturing tool of claim 18, configured to heat the interface piece to a temperature of at least 500°C.
